(19) United States
(12) Patent Application Publication
(10) Pub. No.: US 2011/0186890 A1
(43) Pub. Date: Aug. 4, 2011

(54) Electro-optical Organic Component

(75) Inventors: Carsten Rothe, Dresden (DE); Domagoj Pavici, Dresden (DE)

(73) Assignee: Novaled AG, Dresden (DE)

(21) Appl. No.: 12/937,208

(22) PCT Filed: Apr. 9, 2009
(86) PCT No.: PCT/DE2009/000454

§ 371 Date: Dec. 17, 2010

(30) Foreign Application Priority Data
Apr. 11, 2008 (DE) 10 2008 018 663.5

(51) Int. Cl. H01L 51/52

(52) U.S. Cl. 257/98; 257/E51.018

(57) ABSTRACT

The invention relates to an electro-optic organic component, in particular an organic light-emitting diode, with a layered assembly (2) on a substrate (1), wherein the layered assembly (2) is formed with an electrode (3) and a counter-electrode (4) as well as an organic area (5), encompassing a light-emitting layer, arranged between the electrode (3) and the counter-electrode (4) and wherein the layered assembly (2) has an optical double-refracting antireflective layer structure (6) which is formed on the electrode (3) or the counter-electrode (4).

### FIELD OF THE INVENTION

The invention relates to an electro-optic organic construction element, in particular an organic light-emitting diode.

### BACKGROUND OF THE INVENTION

Because of their unique properties as thin, flat light emitters, Organic Light-Emitting Diodes (OLED) are ideal as an active element for use in displays or for general illumination. Very good internal quantum yields (relationship of the generated photons to the injected electrons) are already currently being achieved. Internal quantum yields are particularly being achieved which almost reach the theoretical limit of 100% through use of phosphorescent emitter materials.

However, not all of the light by far which is generated within the organic layers is also taken out of the component. The refraction index of almost all organic materials and the required transparent electrode materials, in particular Indium Tin Oxide (ITO), which are used to build organic light-emitting diodes, varies in the range from 1.7 to about 2.1. If such a light-emitting diode is applied to a transparent carrier substrate and the usable light is decoupled through the carrier substrate, one speaks of the so-called bottom-emitting arrangement.

All typically used substrate materials, in particular glass carriers or polymer foil, have a refraction index of about 1.5. Therefore there is a leap in the refraction index from a high to a low refraction index during passage of the light from the organic layered construction into the carrier or substrate material. This leap in the refraction index results in part of the light generated inside the organic layers be reflected back into the organic layers. Furthermore, total reflection occurs from a certain limit angle (measured perpendicular to the layered assembly). This means that light which was generated within the organic layers with an angle greater than the limit angle never leaves the organic layers. This light is usually absorbed at the electrodes and is therefore not available as usable light. Furthermore, qualitatively similar reflection losses occur at the boundary surface between the carrier substrate and the air (refraction index ˜1.0).

Apart from the bottom-emitting design described above, OLEDs are also manufactured in a top-emitting design. The light, in this case, does not pass through the carrier substrate but is decoupled in the opposite direction using an electrode which is transparent to light. Therefore it is also possible to use opaque carrier substrates in this geometry such as metal foils. There is also a leap in the refraction index in this design for passage of light from the highly refracting layers which the OLED or their encapsulation produce into the air.

The actually achieved light decoupling efficiencies depend for both the above-mentioned standard OLED configurations from a number of parameters. One particularly important factor here is the refraction indices of all materials used. Furthermore, the light yield is usually improved if the internal light distribution, which is dependent on the angle, is pointed to the front. Nevertheless only a maximum of 25 to 35% of the internally generated light is decoupled even for the best OLEDs in above-mentioned configurations.

Light which is trapped because of an over-critical angle in the carrier substrate can be partially decoupled through structuring of the surface. Typical micro-optic structures in this case are pyramids or lenses. One further possibility to improve decoupling of light in the carrier substrates is to apply diffuser layers.

One further method to decouple light from the organic layers is to apply antireflecting coatings to the critical boundary surfaces which show leaps in the retraction index. For example, some such single or multi-layered, optical antireflecting coatings based on the phenomenon of interference are extensively described in the document EP 1 435 761.

Furthermore an OLED is disclosed in document EP 1 100 129 B1 for which there is a low refracting intermediate layer, that is a low refraction index layer, placed between a transparent ITO electrode and the glass carrier. Improved decoupling of the light is achieved from the OLED layers in the glass substrate, in this case, if the intermediate layer has a refraction index which is as far as possible below the refraction index of the glass substrate, that is less than 1.5.

There is, furthermore, also the possibility of decoupling light from top-emitting OLEDs by applying a finishing layer on the uppermost electrode of the OLED which is semi-transparent to light. As disclosed in the example given in document US 2005/285510, the best results are obtained with layers with the highest possible refracting layers.

The above-mentioned examples for improving light decoupling from OLEDs are based on the phenomenon of interference of light on thin layers. The question of which layer thicknesses and which refractive indices are preferred is dependent on both refractive indices of the crossover point to be made antireflective. For example, in order to minimise the reflection of light with a wave length λ at the boundary surface between two materials with the refraction indices n₁ and n₃, a material with a refraction index n₂ according to n₂=\sqrt{n₁×n₃} should be selected. Furthermore, the ideal layer thickness d is calculated using the formula

$${n}_{2} \times d = \frac{λ}{4} \times N$$

whereby N is any desired whole number. In this example the reflection is minimal for light of exactly a wave length which is arrives exactly perpendicular to the antireflective surface. In other words: decoupling of light which is emitted perpendicular to the carrier substrate is indeed optimised. On the other hand, the reflection increases successively with ever greater internal solid angles. For a solid angle significantly greater that zero degrees the effect of the antireflective layer inverts into the negative, which means that, for this range of solid angles, the reflection increases due to the antireflective layer. Light which is generated below all internal solid angles should ideally be decoupled, particularly for illumination purposes and not just that which leaves the OLED at 90° to its surface.

The suggestion is made in this connection in document WO 05/104261 to minimise the reflectivity integrated over all solid angles to improve light decoupling from certain building elements. According to this procedure, one should generally select layer thicknesses in such a way that light which is generated in the organic layers at a solid angle which deviates from zero is optimally decoupled. In this way the reflection losses are minimal at an angle not equal to zero—all other solid angles demonstrate high reflection losses.

The known configurations for increasing the efficiency of light decoupling are only ideal for a certain solid angle. Light which impinges upon the organic layers at other solid angles at the boundary layer of the OLED is decoupled comparatively poorly. Therefore the efficiency of the above-mentioned structures based on the interference principle is limited.

### SUMMARY OF THE INVENTION

The object of the invention is to provide an improved electro-optic organic building element, in particular light-emitting organic diodes, for which the efficiency of light decoupling is optimised.

This object is achieved according to this invention by means of an electro-optic organic component according to independent claim 1. Advantageous embodiments of the invention are the object of the dependent sub-claims.

The invention embraces the idea of having an electro-optic organic component, in particular an organic light-emitting diode, with a layered assembly on a substrate, wherein the layered assembly is formed with an electrode and a counter-electrode as well as an organic area, encompassing a light-emitting layer, arranged between the electrode and the counter-electrode and wherein the layered assembly has an optical double-refracting antireflective layer structure which is formed on the electrode or the counter-electrode.

To our surprise it has been possible to demonstrate that improved efficiency for decoupling of light is achieved for light generated in the layered assembly using the optically double-refracting antireflective layer structure, which can be integrated in so easily when manufacturing the organic building elements. The optical properties of the layered assembly are altered through optimisation of the light decoupling. For this application, optically double-refracting means that an optical refraction index in the direction of the layered structure of the layered assembly is different to an optical refraction index in a direction transverse to the layered structure of the layered assembly. Back reflections of the light generated in the layered assembly are suppressed by means of the optically double-refracting antireflective layer structure which is created in optical contact with the layered assembly. The transmission which is increased in this way leads to improved light decoupling, which increases the external quantum yield. The optically double-refracting antireflective layer structure can be made in direct contact with the electrode or counter-electrode or separately from this by means of an intermediate area.

One preferred further development of the invention provides the optically double-refracting antireflective layered structure formed with one layer.

In the ease of a purposeful embodiment of the invention it is possible to provide the optically double-refracting antireflective layered structure formed of multiple layers.

One advantageous embodiment of the invention provides an optical refraction index in a direction parallel to the layered structure of the layered assembly in the optically double-refracting antireflective layer structure which is larger than an optical refraction index in a direction perpendicular to the layered structure of the layered assembly. Such a design can be particularly created in connection with use of metallic, non-transparent electrodes.

One preferred further development of the invention provides the optical refraction index in a direction parallel to the layered structure of the layered assembly in the optically double-refracting antireflective layer structure which is less than the optical refraction index in a direction perpendicular to the layered structure of the layered assembly. Such a design is possible, for example, in combination with optically transparent electrodes, for example those made out of ITO.

In the case of one advantageous embodiment of the invention it is possible to provide for a relative difference between the optical refraction index in a direction parallel to the layered structure of the layered assembly and the optical refraction index in a direction perpendicular to the layered structure of the layered assembly that is at least 3%. A preferred design is rather more one in which the highest possible difference is selected since the positive effects increase in this case. Hardly any significant effects were noticed for values below 3%. Use, in particular, of so-called meta-materials allows one to obtain a high double-refraction effect.

One further development of the invention provides the optically double-refracting antireflective layer structure formed on the counter-electrode which is designed as a cover electrode and integrated into a component encapsulation.

One preferred further development of the invention provides the optically double-refracting antireflective layer structure made from a material selected from the following group of materials: crystalline oxide material such as rutile and organic material. Examples of preferred materials are a polymer film or a polymer foil. It is also possible to provide for application of double-refractive organic films by means of vaporisation of suitable organic molecules. It also possible to provide for other sublimatable molecules.

In one purposeful embodiment of the invention it is possible to provide the optically double-refracting antireflective layer structure formed on the electrode or the counterelectrode and is in direct contact with the electrode or the counter-electrode. One alternative to this design can be conceived where the optically double-refracting antireflective layer structure is separated from the electrode or counter-electrode by an intermediate layer area.

One advantageous embodiment of the invention provides the electrode formed as a substrate-side electrode and an intermediate layer formed on the substrate-side electrode with an optical refraction index which is larger than an optical refraction index of the substrate. In this preferred design of the electro-optical organic component it is an embodiment which can be used independently of provision of the optically double-refracting antireflective layer structure and can already lead to improved decoupling of light on its own. In this case an electro-optic organic building element, in particular a light-emitting organic diode, is created with a layered assembly on a substrate whereby the layered assembly is created with an electrode and a counter-electrode as well as an encompassing organic area with a light emitting layer located between electrode and a counter-electrode, whereby the electrode is made as a electrode on the substrate side and there is an intermediate layer on the electrode on the substrate side with an optical refraction index which is greater that an optical refraction index of the substrate itself. The substrate is usually designed as a substrate layer. In one design the intermediate layer can be created by means the optically double-refracting antireflective layer structure. In one preferred further development the intermediate layer is made out of TiO2 for example in combination with a semitransparent electrode made out of silver which is applied on its side to a glass substrate. One layer made out of TiO2 has a refraction index of about 2.6.

One preferred further development of the invention provides for an optical refraction index in the intermediate layer greater than 1.5 and preferably greater than 2.5. Higher refraction indices were selected whereby currently available materials have a refraction index of up to about 3.2.

For one advantageous embodiment of the invention is possible to provide the intermediate layer formed with a layer thickness whose layer thickness value is of the order of magnitude of the wave length of the light generatable in the light-emitting layer, namely about 30 nm to about 1000 nm. The layer thickness must be a multiple of the quarter of the wave length of the decoupled light to obtain an optimal effect. For an intermediate layer with n=3 and light of the wave length of 400 nm (a minimum value), this means a minimum layer thickness of 30 nm. The antireflective property is based on interference and therefore requires coherent light. The light is incoherent for very thick layers a very thick intermediate layer leads to incoherent light and therefore acts like a substrate.

One further development of the invention provides for the intermediate layer being formed on the electrode on the substrate side and therefore being in direct contact with this.

For one preferred further development of the invention it possible to provide the layered assembly formed according to at least one type of construction selected from the following group of types of construction: top-emitting design, bottom-emitting design and transparent design.

There is furthermore a process provided for manufacturing an electro-optical organic construction element according to one or more of the previously described embodiments for which a substrate is applied to a layered assembly, whereby the layered assembly is made up of an electrode and counter electrode as well as an extensive light emitting layer located between the electrode and counter electrode and whereby the layered assembly is manufactured with an optical double-refracting antireflective layer structure which is created on the electrode or counter electrode. In a similar way, there is a process provided for manufacturing an electro-optical organic construction element for which the electrode is designed as an electrode on the substrate side and for which there is an intermediate layer manufactured on the electrode on the substrate side with an optical refraction index which is greater than an optical refraction index of the substrate. Known processes can be used for creating the individual layers in combination with manufacture of organic light-emitting construction elements as such. For example, these include depositing of organic layers using vacuum vaporisation. It is also possible for double-refracting polymer foils to be laminated onto the top-emitting components. Laminating takes place on the substrate in the case of a bottom-emitting component. Double-refracting layers can also be created by means of sputtering of suitable materials, in particular oxide materials. The processes known as such can also be used for implementation of processing steps according to the above-mentioned variations of the electro-optical organic components.

### BRIEF DESCRIPTION OF THE FIGURES

The invention is explained below in more detail in various embodiments with reference to figures of a drawing. They show:

FIG. 1 a schematic representation of an electro-optical organic component with an optical double-refracting antireflective layer structure,

FIG. 2 a graphical presentation for calculations of an effective optical layer thickness depending on the solid angle for various optically double-refracting antireflective layer structures,

FIG. 3 a schematic representation of an electro-optical organic component with an optical double-refracting antireflective layer structure in a bottom-emitting design,

FIG. 4 a graphical presentation for the light decoupling efficiency for an electro-optic organic component in the design according to FIG. 3 as a function of an internal solid angle and the refraction index for the optically double-refracting antireflective layer structure, and

FIG. 5 a graphical presentation for the light decoupling efficiency depending on the solid angle for an electro-optic organic component in the design according to FIG. 3, for which an optically double-refracting antireflective layer structure is created, as well as without an optically double-refracting antireflective layer structure.

FIG. 1 shows a schematic representation of an electro-optical organic component which, for example, is designed as a light-emitting organic diode (OLED). There is a layered assembly 2 a carrier substrate 1 with an electrode 3 and a counter-electrode 4 as well as an encompassing light emitting layer organic area 5 located between the electrode 3 and the counterelectrode 4. The electrode 3 is designed as a light-reflecting metal layer. The counter-electrode 4 is made out of an optically transparent material, for example a thin, semi-transparent metal layer or an oxide layer. Through applying an electrical voltage to the electrode 3 and counter-electrode 4 charge carriers, namely electrons and holes, are injected into the organic area 5 and recombine there in the area of the light-emitting layer, designed as a single layered or multi-layered assembly, giving out light.

There is a light decoupling layer applied to the counter-electrode 4 in the form of an optically double-refracting antireflective layer structure 6 which can be made single-layered or multi-layered. Depending on the concrete design of the counter-electrode 2, the optical refraction index in the optically double-refracting antireflective layer structure 6 in the direction of the layered structure can be larger or smaller than the optical refraction index the direction transverse to the layered structure. Thus, for the design of the counter-electrode 4 as a metal layer, preferably the optical refraction index perpendicular or parallel to the layered structure is greater than that in the direction of the layered structure, n parallel<n perpendicular. On the other hand, the relationship of the refraction indices is the opposite when using a transparent oxide layer for the counter-electrode 4, that is n parallel>n perpendicular.

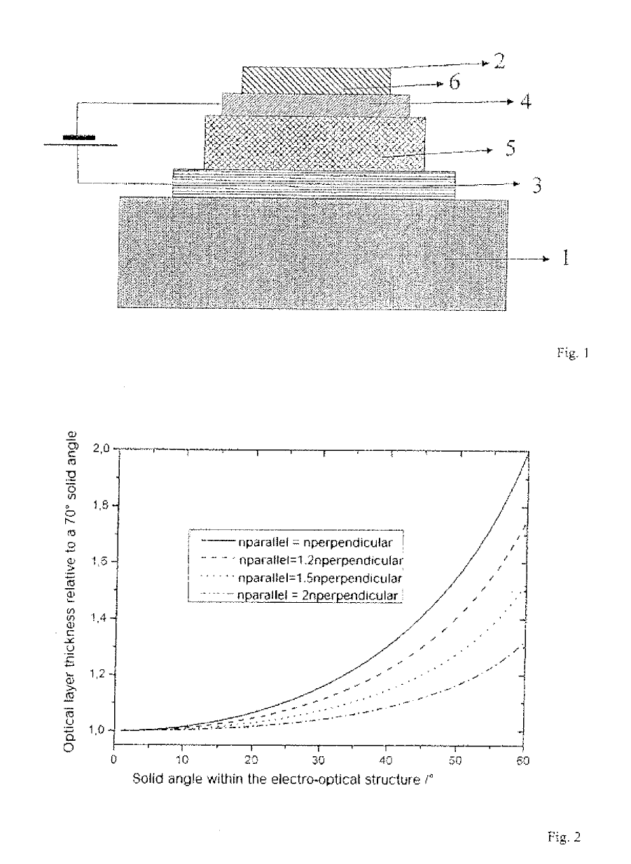

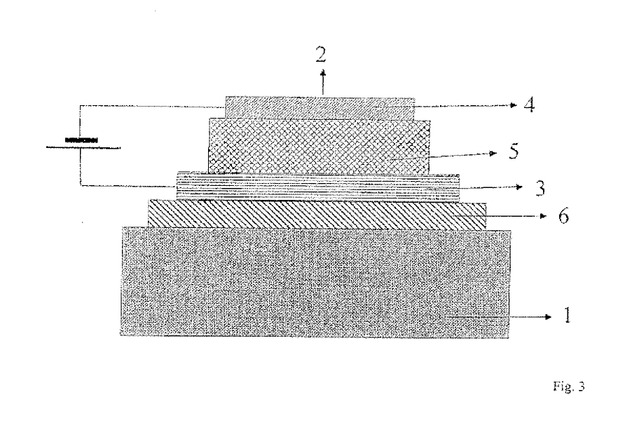

FIG. 2 shows a graphical presentation for calculations of an effective optical layer thickness depending on the solid angle for various optically double-refracting antireflective layer structures.

FIG. 2 contains summarised views concerning the optical thickness of a antireflective layer in connection with a counter-electrode which is semi-transparent to light in a design as a metal layer. An optimal antireflective effect is achieved in this case if the optical thickness of the antireflective layer structure, defined by refraction index x layer thickness, is a multiple of λ/4, whereby λ is the wave length of the light to be decoupled:

n×d=λ/4×N (1)

n represents the optical refraction index of the antireflective layer, d is the layer thickness of the antireflective layer and N is any desired whole number.

These ideal conditions are a consequence of the minimum reflection but can be only reached for a singular solid angle. The layer thickness is typically selected in such a way that the reflection is perpendicular to the surface of the layered structure which means that it is minimal at a zero degree solid angle. The effective layer thickness for another solid angle, α, measured perpendicular to the surface of the components is then given by:

$$d ( α ) = - \frac{d}{cos ( α )} \qquad ( 2 )$$

The optical layer thickness is correspondingly too thick to achieve an optimal (minimal) reflection. When using the suggested double-refracting materials as a decoupling layer or antireflective layer structure it is possible to at least partially if not completely compensate for this effect. Based on simple considerations the following applies in this case for the optical layer thickness:

n(α)×d(α)=d{square root over ((tan(α))²n_{perpendicular}²+nₚₐᵣₐₗₗₑₗ²)} (3)

whereby n_{perpendicular} and nₚₐᵣₐₗₗₑₗ are the respective fraction indices of the optical double-refracting antireflective layer structure, perpendicular and parallel to the layered assembly.

To illustrate the previously described relationship, the optical layer thickness is shown in FIG. 2 as a function of the internal solid angles for various adopted double-refracting materials. For a solid angle of zero degrees the optical layer thickness for all materials is the same which means that, for an ideal selection of the layer thickness of the antireflective layer structure according to the equation (1) above, the best, minimum reflection is achieved here equally for all materials. The effective optical layer thickness increases continuously as the solid angle increases. The reflection losses also increase as a consequence of this since the equation (1) is no longer optimally fulfilled.

However, the effective optical layer thickness for the shown double-refracting materials increases significantly more slowly than for a non double-refracting material. For example, at an internal solid angle of 60° the effective optical layer thickness for the standard material is already 100% too thick—and the reflection losses are appropriately high. In comparison to this (see FIG. 2) the increase in layer thickness for a double-refracting material, defined by 2×n_{perpendicular}=nₚₐᵣₐₗₗₑₗ, at 60° is only 30%. Therefore the total reflection (integrated over all solid angles) of the antireflective layer structure, using a double-refracting material, is significantly reduced. Thus the decoupling efficiency of the component is increased which optimises the external quantum efficiency.

FIG. 3 shows a schematic representation of an electro-optical organic component with an optical double-refracting antireflective layer structure in a bottom-emitting design. The same reference signs are used for the same features in FIG. 3 as were used in FIG. 1.

In contrast to the electro-optical organic component shown in FIG. 1, in the configuration shown in FIG. 3 the optically double-refracting antireflective layer structure 6 is placed on the electrode 3. The optically double-refracting antireflective layer structure 6 is located between the carrier substrate 1 and the electrode 3. The antireflective layered structure 6 is in direct contact with the electrode 3 in the embodiment shown. The descriptions given for FIG. 1 apply appropriately concerning the design of the optical double-refracting antireflective layer structure 6 as well as the other layers of the component.

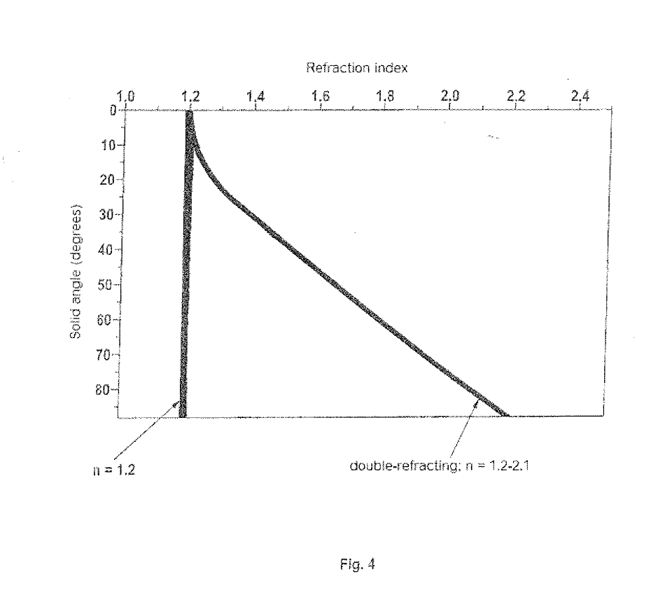

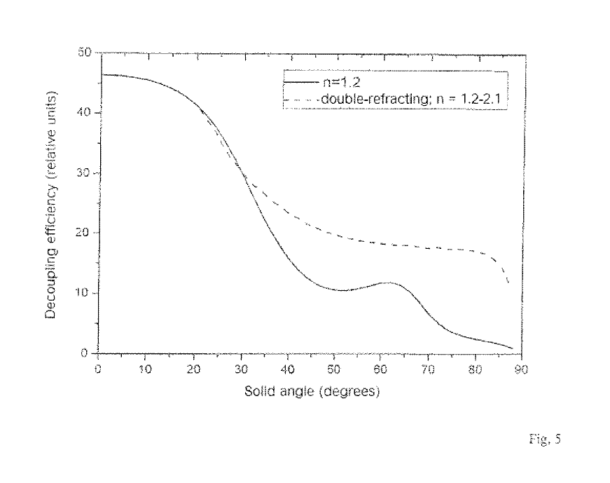

FIG. 4 shows a graphical presentation for the light decoupling efficiency for an electro-optic organic component in the design according to FIG. 3 as a function of an internal solid angle and the refraction index for the optically double-refracting antireflective layer structure.

The software package Etfos was used for component simulations, which is based on an exact solution of the Fresnel formula and not just simple ray tracing. The details of the layer construction used are as follows: glass substrate (n=1.5)/antireflective layer (60 nm, n variable)/ITO (90 nm)/organic layer (60 nm, n=1.7)/emitting layer (0 nm)/organic layer (60 nm, n=1.7)/aluminium (100 nm).

Using a form of graded shading, FIG. 4 shows the decoupling efficiency of the organic layers in the glass substrate as a function of the internal solid angle and as a function of the refraction index of the antireflective layer structure, whereby the lighter the shading the better the decoupling efficiency. It follows that it is advantageous for improved decoupling in a forwards direction (internal solid angle is zero degrees) if the antireflective layer structure has the lowest possible refraction index of, for example, 1.2. On the other hand, better decoupling for a higher solid angle is achieved with higher refraction indices. This effect can be used in that a double-refracting material is used as the antireflective layer which parallel has a higher refraction index than perpendicular to the layered structure, nₚₐᵣₐₗₗₑₗ<n_{perpendicular}.

Similar simulations on components for which the electrode is designed as a semitransparent metal layer show that, in this case, the refraction index perpendicular to the layered structure should be made greater than that parallel to it, nₚₐᵣₐₗₗₑₗ<n_{perpendicular} for the design of the double-refracting antireflective layer.

In order to demonstrate this more clearly the course of the refraction index is shown in FIG. 4 for two hypothetical materials as a function of the internal solid angle. A constant refraction index of 1.2 was selected for a non double-refracting material in order to achieve the maximum light decoupling in a forwards direction. In contrast to this, the refraction index increases continuously as a function of the internal solid angle for the double-refracting material and therefore preferably follows the maximum decoupling efficiency for the respective solid angle.

FIG. 5 is a graphical presentation for the light decoupling efficiency depending on the solid angle for an electro-optic organic component in the design according to FIG. 3, for which an optically double-refracting antireflective layer structure is created (dashed line), as well as without an optically double-refracting antireflective layer structure (solid line).

It follows that the decoupling efficiency of the double-refracting material is significantly greater than that of the non double-refracting material. According to the integrations of the data shown in FIG. 5 over all solid angles there is a 27.5% higher overall decoupling efficiency for the double-refracting material compared to that achieved using non double-refracting material with a constant refraction index of 1.2.

The features of the invention disclosed in the description above, the claims and the figures can be used individually as well as in any desired combination to realise the invention in its various embodiments of importance.

1. An electro-optic organic component, comprising:
a layered assembly on a substrate, wherein the layered assembly comprises an electrode and a counter-electrode, wherein an organic area comprising a light-emitting layer is arranged between the electrode and the counter-electrode, and wherein the layered assembly comprises an optical double-refracting antireflective layer structure arranged on the electrode or the counter-electrode.

2. The component according to claim 1, wherein the optically double-refracting antireflective layered structure comprises one layer.

3. The component according to claim 1, wherein the optically double-refracting antireflective layered structure comprises multiple layers.

4. The component according to claim 1, wherein the optically double-refracting antireflective layer structure comprises an optical refraction index in a direction parallel to the layered structure of the layered assembly larger than an optical refraction index in a direction perpendicular to the layered structure of the layered assembly.

5. The component according to claim 1, wherein the optically double-refracting antireflective layer structure comprises an optical refraction index in a direction parallel to the layered structure of the layered assembly less than the optical refraction index in a direction perpendicular to the layered structure of the layered assembly.

6. The component according to claim 4, wherein a relative difference between the optical refraction index in a direction parallel to the layered structure of the layered assembly and the optical refraction index in a direction perpendicular to the layered structure of the layered assembly is at least about 3%.

7. The component according to claim 1, wherein the optically double-refracting antireflective layer structure is arranged on the counter-electrode, which comprises a cover electrode integrated into a component encapsulation.

8. The component according to claim 1, wherein the optically double-refracting antireflective layer structure comprises a material selected from the group consisting of: crystalline oxide material, and organic material.

9. The component according to claim 1, wherein the optically double-refracting antireflective layer structure is arranged on the electrode or the counter-electrode, and is in direct contact with the electrode or the counter-electrode.

10. The component according to claim 1, wherein the electrode comprises a substrate-side electrode comprising an intermediate layer with an optical refraction index which is larger than an optical refraction index of the substrate.

11. The component according to claim 10, wherein the optical refraction index of the intermediate layer is larger than about 1.5.

12. The component according to claim 10, wherein the intermediate layer comprises a layer thickness of the order of magnitude of the wave length of the light generatable in the light-emitting layer.

13. The component according to claim 10, wherein the intermediate layer is arranged on the substrate-side electrode and is in direct contact with the substrate-side electrode.

14. The component according to claim 1, wherein the layered assembly comprises at least one type of construction selected from the group consisting of: top-emitting design, bottom-emitting design, and transparent design.

15. The component according to claim 5, wherein a relative difference between the optical refraction index in a direction parallel to the layered structure of the layered assembly and the optical refraction index in a direction perpendicular to the layered structure of the layered assembly is at least about 3%.

16. The component according to claim. 8, wherein the crystalline oxide material is rutile.

17. The component according to claim 11, wherein the optical refraction index of the intermediate layer is larger than about 2.5.

18. The component of claim 12, wherein the layer thickness of the intermediate layer is from about 30 nm to about 1000 nm.
